(19) United States
(12) Patent Application Publication
(10) Pub. No.: US 2016/0013085 A1
(43) Pub. Date: Jan. 14, 2016

(54) In-Situ Acoustic Monitoring of Chemical Mechanical Polishing

(71) Applicant: Applied Materials, Inc., Santa Clara, CA (US)

(72) Inventors: Xiong Yeu Chew, Singapore (SG); Venaka Rama Subrahmanyam Kommisetti, Singapore (SG); Uday Mahajan, Singapore (SG); Boguslaw A. Swedek, Cupertino, CA (US); Rajeev Bajaj, Fremont, CA (US); Jianshe Tang, Sunnyvale, CA (US)

(21) Appl. No.: 14/328,211

(22) Filed: Jul. 10, 2014

(51) Int. Cl. H01L 21/67; H01L 21/768; B24B 37/005

(52) U.S. Cl. CPC H01L 21/67253; B24B 37/0053; H01L 21/67075; H01L 21/67092; H01L 21/76898; H01L 21/7684; H01L 21/67288

(57) ABSTRACT

A method of controlling chemical mechanical polishing includes polishing a substrate having a plurality of protrusions, monitoring the substrate during polishing with an in-situ monitoring system to generate a signal, the in-situ monitoring system including an acoustic sensor, a motor current sensor or a motor torque sensor, and detecting breakage of the protrusions based on the signal.

### TECHNICAL FIELD

This disclosure relates to in-situ monitoring of chemical mechanical polishing.

### BACKGROUND

An integrated circuit is typically formed on a substrate by the sequential deposition of conductive, semiconductive, or insulative layers on a silicon wafer. One fabrication step involves depositing a filler layer over a non-planar surface and planarizing the filler layer. For certain applications, the filler layer is planarized until the top surface of a patterned layer is exposed. A conductive filler layer, for example, can be deposited on a patterned insulative layer to fill the trenches or holes in the insulative layer. After planarization, the portions of the metallic layer remaining between the raised pattern of the insulative layer form vias, plugs, and lines that provide conductive paths between thin film circuits on the substrate. For other applications, such as oxide polishing, the filler layer is planarized until a predetermined thickness is left over the non planar surface. In addition, planarization of the substrate surface is usually required for photolithography.

Chemical mechanical polishing (CMP) is one accepted method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. An abrasive polishing slurry is typically supplied to the surface of the polishing pad.

One problem in CMP is determining whether the polishing process is complete, i.e., whether a substrate layer has been planarized to a desired flatness or thickness, or when a desired amount of material has been removed. Variations in the slurry distribution, the polishing pad condition, the relative speed between the polishing pad and the substrate, and the load on the substrate can cause variations in the material removal rate. These variations, as well as variations in the initial thickness of the substrate layer, cause variations in the time needed to reach the polishing endpoint. Therefore, the polishing endpoint usually cannot be determined merely as a function of polishing time.

In some systems, the substrate is monitored in-situ during polishing, e.g., by monitoring the torque required by a motor to rotate the platen or carrier head. Acoustic monitoring of polishing has also been proposed. However, existing monitoring techniques may not satisfy increasing demands of semiconductor device manufacturers.

### SUMMARY

A step in the process of fabrication of through silicon vias (TSV) is planarization of any conductive stubs that protrude from the substrate surface. Due to the high aspect ratio of the stubs, there is a danger of stubs breaking off during the polishing process. The presence of broken stubs in the polishing environment can result in severe scratching on the substrate surface. However, acoustic emission sensing and/or motor current monitoring can be used to detect the breakage of the stubs. This permits polishing to be halted quickly after any breakage of a stub to avoid scratching of the substrate. The polishing pad can be flushed to remove any debris to reduce the risk scratching of when polishing resumes. Similarly, the substrate can be cleaned to remove any debris and then be sent back for rework. Alternatively or in addition, that substrate and/or subsequent substrates can be polished with lower down force to reduce the risk of breakage of the stubs.

As noted above, acoustic monitoring of chemical mechanical polishing has been proposed. In general, such systems include an acoustic sensor suspended above the polishing pad, or mounted in the platen or the carrier head. By placing the acoustic sensor in direct contact with the covering layer of the polishing pad, signal attenuation can be reduced. This can provide more accurate monitoring or endpoint detection. This acoustic sensor can be used in the detection of breakage of TSV stubs as discussed above, or for endpoint detection in other polishing processes, e.g., to detect removal of a filler layer and exposure of an underlying layer.

In one aspect, a method of controlling chemical mechanical polishing includes polishing a substrate having a plurality of protrusions, monitoring the substrate during polishing with an in-situ monitoring system to generate a signal, the in-situ monitoring system including an acoustic sensor, a motor current sensor or a motor torque sensor, and detecting breakage of the protrusions based on the signal.

Implementations may include one or more of the following. Detecting breakage may include comparing signal intensity to a threshold value. The signal intensity may be calculated from a root mean square of the signal. A Fast Fourier Transform may be performed on the signal to generate a transformed signal, and the signal intensity may be calculated based on an intensity of a frequency band of the transformed signal. A wavelet packet transform may be performed on the signal to generate a plurality of signal components, and the signal intensity may be calculated based on an intensity of a signal component. Polishing may be halted upon detecting breakage of the protrusions. Detecting breakage of the protrusions may trigger reducing a pressure and/or a relative speed of polishing for a subsequent substrate.

In another aspect, a non-transitory computer-readable medium has stored thereon instructions, which, when executed by a processor, causes the processor to perform operations of the above method.

In another aspect, a chemical mechanical polishing system includes a platen to support a polishing pad, a carrier head to hold a substrate in contact with the polishing pad, an in-situ monitoring system to generate a signal, the in-situ monitoring system including an acoustic sensor, a motor current sensor or a motor toque sensor, and a controller configured to receive the signal from the in-situ monitoring system and to detect breakage of protrusions on the substrate based on the signal.

In another aspect, a chemical mechanical polishing apparatus includes a platen, a polishing pad supported on the platen, and an in-situ acoustic monitoring system to generate a signal. The polishing pad includes a polishing layer and a backing layer, the backing layer having an aperture therethrough. The in-situ acoustic monitoring system includes an acoustic sensor supported by the platen and extending through the aperture in the backing layer to contact the polishing layer.

Implementations can include one or more of the following potential advantages. Breakage of TSV stubs can be detected. The risk of scratching from broken stubs of can be reduced. An acoustic sensor can have a stronger signal. Exposure of an underlying layer can be detected more reliably. Polishing can be halted more reliably, and wafer-to-wafer uniformity can be improved.

The details of one or more embodiments are set forth in the accompanying drawings and the description below. Other aspects, features and advantages will be apparent from the description and drawings, and from the claims.

### DESCRIPTION OF DRAWINGS

FIGS. 1A-1E illustrate fabrication of through silicon vias.

FIG. 2 illustrates a schematic cross-sectional view of an example of a polishing apparatus.

FIG. 3 is a flow chart illustrating a method of controlling polishing.

Like reference symbols in the various drawings indicate like elements.

### DETAILED DESCRIPTION

In some semiconductor chip fabrication processes an overlying layer, e.g., metal, silicon oxide or polysilicon, is polished until an underlying layer, e.g., a dielectric, such as silicon oxide, silicon nitride or a high-K dielectric, is exposed. For some applications, it may be possible to optically detect the exposure of the underlying layer. For some applications, the underlying layer has a different coefficient of friction against the polishing layer than the overlying layer. As a result, when the underlying layer is exposed, the acoustic signal from the substrate will change. In addition, the torque required by a motor to cause the platen or carrier head to rotate at a specified rotation rate can change. The polishing endpoint can be determined by detecting this change in acoustic signal and/or motor torque.

One area of development in integrated circuit fabrication is three-dimensional integrated circuits (3D ICs) that include multiple stacked semiconductor wafers. Such 3D ICs use through-silicon-vias (TSV), e.g., conductive vias that extend entirely through the semiconductor wafer, to provide electrical connections between multiple wafers.

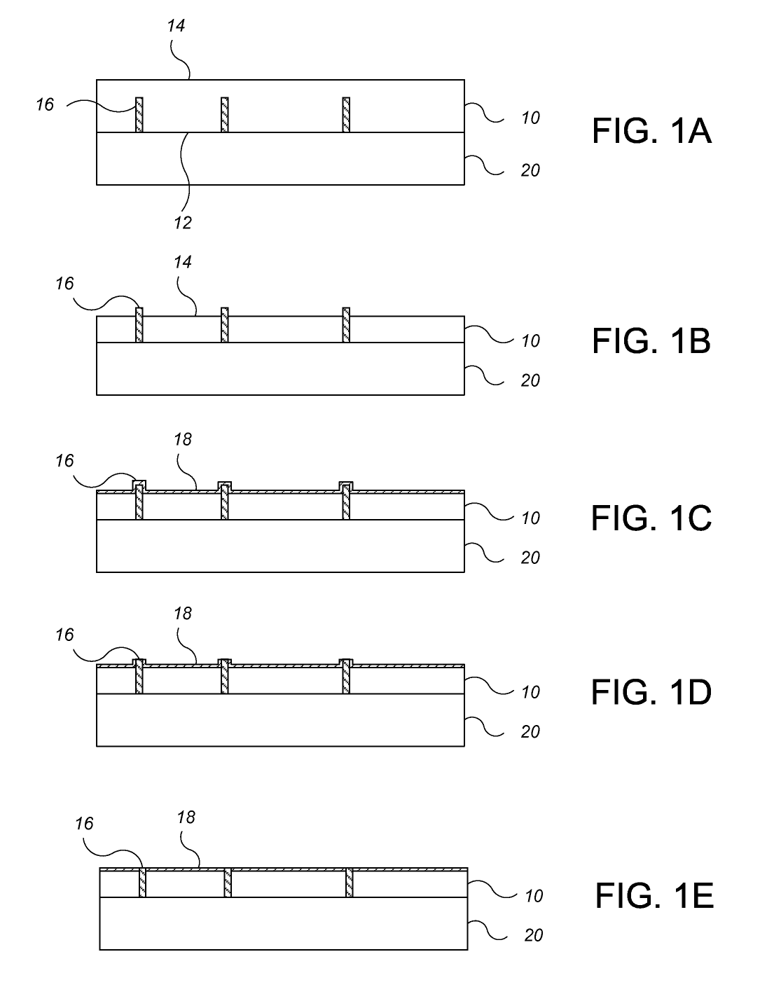

The process of TSV fabrication includes a backside via reveal (BVR). Referring to FIG. 1A, the process typically begins with a semiconductor device wafer 10 that includes conductive vias 16 in the top surface 12. The conductive vias extend partially through the device wafer 10. The conductive vias 16 can be formed of metal, e.g., copper. A barrier layer, e.g., Ti or TiN, can line the vias 16 and cover the tops surface 12 of the wafer 10. The top surface 12 of the device wafer 10 is bonded to a handling substrate 20 with an adhesive 16.

As shown in FIG. 1B, the backside 14 of the device wafer 10 is then thinned by grinding or polishing to a target thickness, e.g., between 50 and 100 microns. The backside 14 of the device wafer 10 is then subjected to a silicon etch, e.g., a wet or dry etch, to expose the vias 16. Due to the adhesive and thickness variations and grinding non-uniformity, a total thickness variation of 3-6 microns can be expected. Therefore the etch process may need to remove 3-6 microns of the silicon to ensure full exposure of the vias 16 across the wafer. However, due to the thickness variations, this etch leaves some vias 16 protruding from the thinned backside surface 14 of the device wafer 10.

As shown in FIG. 1C, a dielectric film 18 is then deposited for passivation on the thinned backside of the silicon wafer 10. As shown in FIG. 1D, a chemical mechanical polishing step is performed to remove the dielectric cap from the protruding vias 16. In addition, as shown in FIG. 1E, a further chemical mechanical polishing step is then performed to planarize the backside of the substrate so that the vias 16 are flush with the surrounding surface of the dielectric film 18. The backside of the substrate can then be polished further until the dielectric film 18 is at a target thickness. The handling substrate 20 can then be removed, e.g., after the device wafer 10 is bonded to another device wafer to form part of the stack in the 3D IC.

The protruding stubs of the TSVs, i.e., the portions of the vias 16 that extend above the surrounding generally planar surface of the dielectric film 16, can have a relatively high aspect ratio. In addition, the stubs can be formed of materials with a variety of stiffnesses, e.g., low temperature oxides, nitrides, barrier layer and copper. copper. Moreover, due to the total thickness variation, some stubs can protrude higher than other stubs. As a result, there is a danger of breaking the stubs, particularly the higher protruding stubs, during the polishing process. The presence of broken stubs in the polishing environment can result in severe scratching on the substrate surface. Moreover, fracturing of the TSVs can lead to reduction of yield and reliability during downstream integration. However, as discussed further below, acoustic emission sensing and/or motor current/torque monitoring can be used to detect the breakage of the stubs. In addition, acoustic emission sensing can be used to sense planarization of the substrate, i.e., when the TSVs become planar with the surrounding surface of the dielectric film.

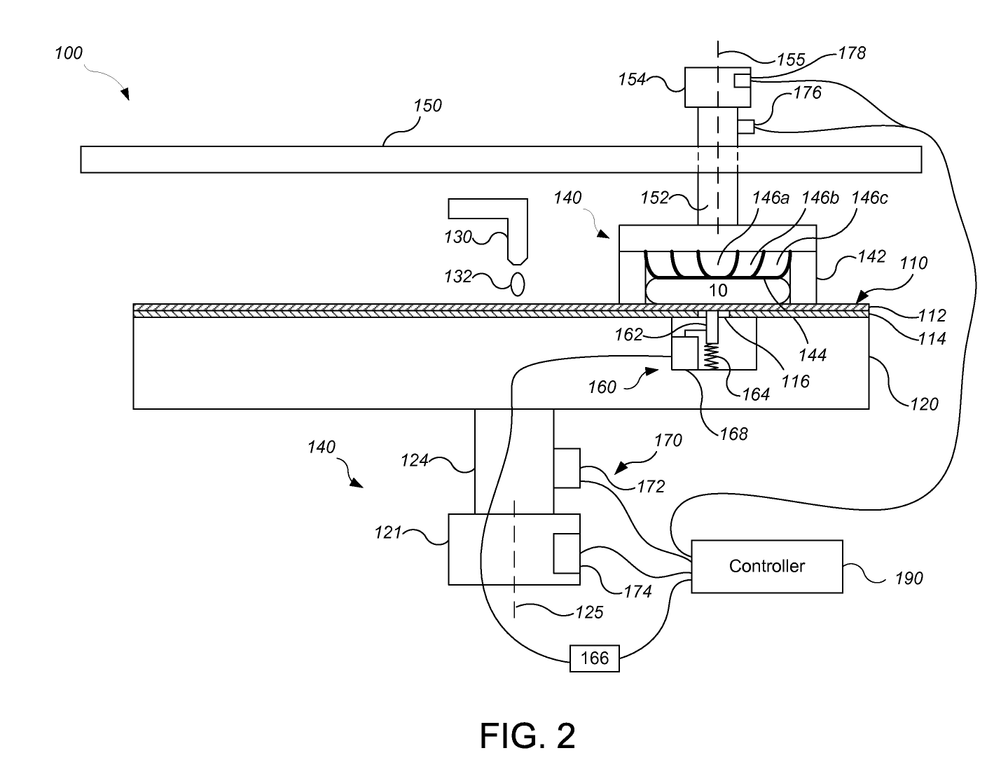

FIG. 2 illustrates an example of a polishing apparatus 100. The polishing apparatus 100 includes a rotatable disk-shaped platen 120 on which a polishing pad 110 is situated. The polishing pad 110 can be a two-layer polishing pad with an outer polishing layer 112 and a softer backing layer 114. The platen is operable to rotate about an axis 125. For example, a motor 121, e.g., a DC induction motor, can turn a drive shaft 124 to rotate the platen 120.

The polishing apparatus 100 can include a port 130 to dispense polishing liquid 132, such as abrasive slurry, onto the polishing pad 110 to the pad. The polishing apparatus can also include a polishing pad conditioner to abrade the polishing pad 110 to maintain the polishing pad 110 in a consistent abrasive state.

The polishing apparatus 100 includes at least one carrier head 140. The carrier head 140 is operable to hold a substrate 10 against the polishing pad 110. Each carrier head 140 can have independent control of the polishing parameters, for example pressure, associated with each respective substrate.

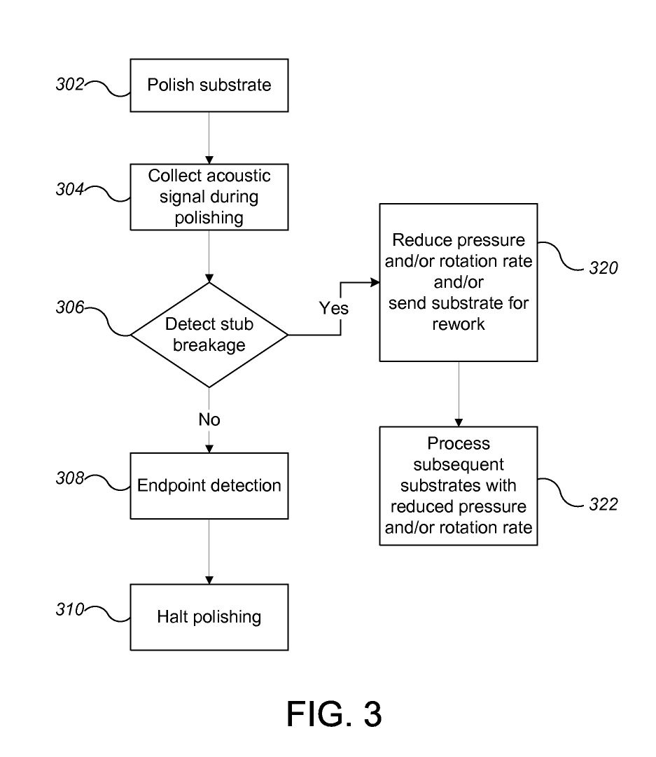

The carrier head 140 can include a retaining ring 142 to retain the substrate 10 below a flexible membrane 144. The carrier head 140 also includes one or more independently controllable pressurizable chambers defined by the membrane, e.g., three chambers 146a-146c, which can apply independently controllable pressurizes to associated zones on the flexible membrane 144 and thus on the substrate 10 (see FIG. 3). Although only three chambers are illustrated in FIGS. 2 and 3 for ease of illustration, there could be one or two chambers, or four or more chambers, e.g., five chambers.

The carrier head 140 is suspended from a support structure 150, e.g., a carousel or track, and is connected by a drive shaft 152 to a carrier head rotation motor 154, e.g., a DC induction motor, so that the carrier head can rotate about an axis 155. Optionally each carrier head 140 can oscillate laterally, e.g., on sliders on the carousel 150, or by rotational oscillation of the carousel itself, or by sliding along the track. In typical operation, the platen is rotated about its central axis 125, and each carrier head is rotated about its central axis 155 and translated laterally across the top surface of the polishing pad.

While only one carrier head 140 is shown, more carrier heads can be provided to hold additional substrates so that the surface area of polishing pad 110 may be used efficiently.

A controller 190, such as a programmable computer, is connected to the motors 121, 154 to control the rotation rate of the platen 120 and carrier head 140. For example, each motor can include an encoder that measures the rotation rate of the associated drive shaft. A feedback control circuit, which could be in the motor itself, part of the controller, or a separate circuit, receives the measured rotation rate from the encoder and adjusts the current supplied to the motor to ensure that the rotation rate of the drive shaft matches at a rotation rate received from the controller.

The polishing apparatus 100 includes at least one in-situ monitoring system. In some implementations, the polishing apparatus includes an in-situ acoustic monitoring system 160. In some implementations, the polishing apparatus includes an in-situ motor current or motor torque monitoring system 170. In some implementations, the polishing apparatus includes both an in-situ acoustic monitoring system 160 and an in-situ motor current or motor torque monitoring system 170.

In some implementations, at least one of the in-situ monitoring systems is configured to detect breakage of the stubs of the TSVs. For example, the in-situ acoustic monitoring system 160 and/or the in-situ motor current or motor torque monitoring system 170 can configured to detect breakage of the stubs. However, the in-situ acoustic monitoring system 160 can be used and has some advantages for endpoint detection for a polishing apparatus that is not configured to detect breakage of the stubs.

The in-situ acoustic monitoring system 160 includes an acoustic emission sensor 162 positioned in contact with the polishing pad 110. In the implementation shown in FIG. 2, the acoustic emission sensor 162 is positioned in a recess in the platen 120 and is positioned in contact with an underside of the polishing pad 110. The acoustic emission sensor 162 could also be located above the platen, e.g., held by a support arm, and positioned in contact with the polishing surface. However, as the polishing surface may be rough and be undergoing relative motion, having the sensor 162 in contact with the underside of the polishing pad 110 is advantageous to provide lower noise.

If positioned in the platen 120, the acoustic emission sensor 162 can be located at the center of the platen 120, e.g., at the axis of rotation 125, at the edge of the platen 120, or at a midpoint (e.g., 5 inches from the axis of rotation for a 20 inch diameter platen).

In some implementations, a spring 164 biases the acoustic emission sensor 162 against the polishing pad 110. This can improve reliability of the contact of the sensor 162 to the pad and reduce signal attenuation.

In some implementations, if the polishing pad 110 is a multi-layer pad, an aperture 116 can be formed through the backing layer 114, and the sensor 162 can protrude above the top surface of the platen 120, into the aperture 116 to directly contact the polishing layer 112. As the polishing layer 112 is more rigid than the backing layer 114, placing the sensor 162 in contact with the polishing layer 112 can reduce signal attenuation, thus improving the signal-to-noise ratio.

The portion of the polishing layer 112 above the sensor 162 can be of the same material as the remainder of the polishing pad, e.g., porous polyurethane. In particular, the portion of the polishing layer 112 above the sensor 162 can be opaque. On the other hand, in some implementations, the polishing system 100 also includes an in-situ optical monitoring system. In this case the sensor 162 could be placed in contact with a window that is secured to the polishing pad. However, direct contact with the pad material can reduce signal attenuation.

The sensor 162 can be connected by circuitry 168 to a power supply and/or other signal processing electronics 166 through a rotary coupling, e.g., a slip ring. The signal processing electronics 166 can be connected in turn to the controller 190. The signal from the sensor 162 can be amplified by a built-in internal amplifier with a gain of 40-60 dB. The signal from the sensor 162 can also be run through a high pass filter that can be part of the sensor 162 or the circuitry 168. The high pass filter can filter frequency components lower than, for example, 50-100 Hz. The signal from the sensor 162 can then be further amplified and filtered if necessary, and digitized through an A/D port to a high speed data acquisition board, e.g., in the electronics 166.

A position sensor, e.g., an optical interrupter connected to the rim of the platen or a rotary encoder, can be used to sense the angular position of the platen 120. This permits only portions of the signal measured when the sensor 162 is in proximity to the substrate, e.g., when the sensor 162 is below the carrier head or substrate, to be used in endpoint detection.

The signal from the sensor 162, e.g., after amplification, preliminary filtering and digitization, can be subject to data processing, e.g., in the controller 190, for either endpoint detection or detection of stub breakage.

If the controller 190 is configured to detect breakage of the stubs, then in some implementations the power of the signal from the sensor 162 can be monitored as a function of time. For example, a root mean square (rms) of the signal intensity (across the frequency spectrum and/or over time) can be calculated. If the power of the signal exceeds a threshold value, this indicates breakage of the stubs.

In some implementations, a frequency analysis of the signal is performed. For example, a Fast Fourier Transform (FFT) can be performed on the signal to generate a frequency spectrum. A particular frequency band can be monitored, and if the intensity in the frequency band exceeds a threshold value, this can indicate breakage of the stubs. As another example, a wavelet packet transform (WPT) can be performed on the signal to decompose the signal into a low-frequency component and a high frequency component. The decomposition can be iterated if necessary to break the signal into smaller components. The intensity of one of the frequency components can be monitored, and if the intensity in the component exceeds a threshold value, this can indicate breakage of the stubs.

The threshold value can be determined experimentally. In order to correlate the signal to TSV stub breakage, a first set-up substrate with no stubs can be polished. The first set-up substrate is monitored with the acoustic sensor to generate a baseline signal that is stored. A second set-up substrate with stubs that protrude more than the intended device substrate (e.g., 15 micron protrusion for a 5 micron diameter via) is polished. The polishing parameters, e.g., applied pressure, can be selected such that breakage of the TSV stubs is expected. The second set-up substrate is monitored with the acoustic sensor to generate a second signal that is also stored. The second set-up substrate can then be inspected with an optical microscope or with a scanning electron microscope to confirm that at least some TSV stubs were broken. By comparison of the second signal to the baseline signal, any spikes in signal intensity can be categorized as indicating TSV stub breakage. A threshold value can be selected that is larger than the baseline signal, but smaller than the intensity of the spikes in the second signal.

FIG. 3 illustrates a process for polishing a device substrate, e.g., after the threshold values have been determined experimentally. A device substrate is polished at the polishing station (302) and an acoustic signal is collected from the in-situ acoustic monitoring system (304).

The signal is monitored to detect breakage of the TSV stubs (306). For example, as discussed above, the average signal power, or the intensity of a frequency band, can be monitored and compared to a threshold value.

If no breakage is detected, then the polishing proceeds normally, and the polishing endpoint can be detected (308). The endpoint can be detected using an in-situ optical monitoring system, or using a motor current or motor torque monitoring system 170, or using the acoustic monitoring system 160. Detected of the polishing endpoint triggers halting of the polishing (310), although polishing can continue for a predetermined amount of time after endpoint trigger.

The motor current or motor torque monitoring system 170, or using the acoustic monitoring system 160, can be used to detect when the TSV stubs have been polished to be flush with the surrounding surface. In particular, since the area of the substrate in contact with the polishing pad will increase significantly when the TSV stubs have been removed, this will cause a significant increase in the friction between the polishing pad and substrate. This change in friction can be detected using a motor current or motor torque monitoring system 170. Similarly, the change in friction should cause a change in the acoustic emissions, which can bet detected using the acoustic monitoring system 160.

If breakage is detected, then the controller 190 can cause the polishing system to issue a visual or auditory alert, e.g., generated on the controller 90, or to automatically take corrective action (320). For example, polishing can be halted immediately, the substrate 10 removed from the polishing pad 110, and the polishing pad 110 subjected to cleaning, e.g., a high pressure rinse with a cleaning fluid, to remove any debris. Optionally, the operator can be prompted to rework the wafer, e.g., if the signal exceeds a second threshold. As another example, the pressure applied by the carrier head 140 to the substrate 10 can be reduced, and/or the relative speed between the substrate 10 and the polishing pad 110 can be reduced, e.g., by reducing the rotation rate of the platen 120 and/or carrier head 140.

In addition, the controller 190 can cause subsequent substrates to be polished at reduced pressure and/or relative speed (322) in order to reduce the risk of TSV stub breakage in the subsequent substrates.

In some implementations, the acoustic emission sensor 162 could be positioned in the carrier head 140 to contact the back surface of the membrane 144 or substrate 10, rather than in the platen 120.

In some implementations, the polishing apparatus includes an in-situ motor current or motor torque monitoring system 170. The in-situ monitoring system 170 includes a sensor to measure a motor torque and/or a current supplied to a motor.

For example, a torque meter 172 can be placed on the drive shaft 124 and/or a torque meter 176 can be placed on the drive shaft 152. The output signal of the torque meter 172 and/or 176 is directed to the controller 190.

Alternatively or in addition, a current sensor 174 can monitor the current supplied to the motor 121 and/or a current sensor 178 can monitor the current supplied to the motor 154. The output signal of the current sensor 174 and/or 178 is directed to the controller 190. Although the current sensor is illustrated as part of the motor, the current sensor could be part of the controller (if the controller itself outputs the drive current for the motors) or a separate circuit.

The output of the motor current or motor torque monitoring system 170 can be a digital electronic signal (if the output of the sensor is an analog signal then it can be converted to a digital signal by an ADC in the sensor or the controller).

The signal from the motor current or motor torque monitoring system 170 can be processed in a manner similar to the acoustic signal described above to detect TSV breakage. For example, motor current or motor torque can be subject to an root mean square operation, or a Fast Fourier Transform (FFT) or wavelet packet transform (WPT). The resulting signal, signal bandwidth or signal component can then be compared to an empirically determined threshold to detect TSV stub breakage.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

A computer program (also known as a program, software, software application, or code) can be written in any form of programming language, including compiled or interpreted languages, and it can be deployed in any form, including as a stand alone program or as a module, component, subroutine, or other unit suitable for use in a computing environment. A computer program does not necessarily correspond to a file. A program can be stored in a portion of a file that holds other programs or data, in a single file dedicated to the program in question, or in multiple coordinated files (e.g., files that store one or more modules, sub programs, or portions of code). A computer program can be deployed to be executed on one computer or on multiple computers at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The above described polishing apparatus and methods can be applied in a variety of polishing systems. Either the polishing pad, or the carrier head, or both can move to provide relative motion between the polishing surface and the wafer. For example, the platen may orbit rather than rotate. The polishing pad can be a circular (or some other shape) pad secured to the platen. Some aspects of the endpoint detection system may be applicable to linear polishing systems (e.g., where the polishing pad is a continuous or a reel-to-reel belt that moves linearly). The polishing layer can be a standard (for example, polyurethane with or without fillers) polishing material, a soft material, or a fixed-abrasive material. Terms of relative positioning are used; it should be understood that the polishing surface and wafer can be held in a vertical orientation or some other orientations.

While this specification contains many specifics, these should not be construed as limitations on the scope of what may be claimed, but rather as descriptions of features that may be specific to particular embodiments of particular inventions. In some implementations, the method could be applied to other combinations of overlying and underlying materials, and to signals from other sorts of in-situ monitoring systems, e.g., optical monitoring or eddy current monitoring systems.

What is claimed is:

1. A method of controlling chemical mechanical polishing, comprising:
polishing a substrate having a plurality of protrusions;
during polishing, monitoring the substrate with an in-situ monitoring system to generate a signal, the in-situ monitoring system including an acoustic sensor, a motor current sensor or a motor torque sensor;
detecting breakage of the protrusions based on the signal.

2. The method of claim 1, wherein detecting breakage comprises comparing a signal intensity to a threshold value.

3. The method of claim 2, comprising calculating the signal intensity from a root mean square of the signal

4. The method of claim 2, comprising performing a Fast Fourier Transform on the signal to generate a transformed signal, and calculating the signal intensity based on an intensity of a frequency band of the transformed signal.

5. The method of claim 2, comprising performing a wavelet packet transform on the signal to generate a plurality of signal components, and calculating the signal intensity based on an intensity of a signal component.

6. The method of claim 1, comprising halting polishing upon detecting breakage of the protrusions.

7. The method of claim 1, wherein detecting breakage of the protrusions triggers reducing a pressure and/or a relative speed of polishing for a subsequent substrate.

8. The method of claim 1, wherein the protrusions comprise stubs of through silicon vias in the substrate.

9. A chemical mechanical polishing apparatus, comprising:
a platen to support a polishing pad;
a carrier head to hold a substrate in contact with the polishing pad;
an in-situ monitoring system to generate a signal, the in-situ monitoring system including an acoustic sensor, a motor current sensor or a motor torque sensor;
a controller configured to receive the signal from the in-situ monitoring system and to detect breakage of protrusions on the substrate based on the signal.

10. The apparatus of claim 9, wherein the in-situ monitoring system comprises an acoustic sensor.

11. The apparatus of claim 10, wherein the acoustic sensor projects above a top surface of the platen.

12. The apparatus of claim 9, wherein the controller is configured to compare a signal intensity to a threshold value to detect breakage.

13. The apparatus of claim 12, wherein the controller is configured to perform a root mean square operation, a Fast Fourier Transform (FFT) or a wavelet packet transform (WPT) on the signal.

14. A non-transitory computer-readable medium having stored therein instructions, which, when executed by a processor, causes the processor to perform operations comprising:
receiving, during polishing of a substrate, an acoustic, motor torque or motor current signal from an in-situ monitoring system;
comparing a signal intensity of the signal to a threshold value to detect breakage of protrusions on the substrate; and
at least one of modifying a polishing parameter or generating an alert to a user upon detecting breakage of the protrusions.

15. A chemical mechanical polishing apparatus, comprising:
a platen;
a polishing pad supported on the platen, the polishing pad comprising a polishing layer and a backing layer the backing layer having an aperture therethrough;
an in-situ acoustic monitoring system to generate a signal, the in-situ acoustic monitoring system including an acoustic sensor supported by the platen and extending through the aperture in the backing layer to contact the polishing layer.

16. The apparatus of claim 15, comprising a spring to bias the acoustic sensor against the polishing layer.
